(19) United States
(12) Patent Application Publication
(10) Pub. No.: US 2015/0168531 A1
(43) Pub. Date: Jun. 18, 2015

(54) CALIBRATION PLATE

(71) Applicant: MPI CORPORATION, Zhubei (TW)

(72) Inventors: WEI-CHENG KU, ZHUBEI (TW); HAO WEI, ZHUBEI (TW); CHEN-KANG CHIU, ZHUBEI (TW); SHIN-LAN KAO, ZHUBEI (TW)

(73) Assignee: MPI CORPORATION, ZHUBEI (TW)

(21) Appl. No.: 14/558,625

(22) Filed: Dec. 2, 2014

(30) Foreign Application Priority Data
Dec. 13, 2013 (TW) 102146106

(51) Int. Cl. G01R 35/00; G01R 1/067; G01R 1/04

(52) U.S. Cl. CPC G01R 35/005; G01R 1/0408; G01R 1/067

(57) ABSTRACT

A substrate has a first side and a second side opposite to the first side. The substrate further has a first calibrating region and a second calibrating region on the first side, on each of which two pads are provided, and the pads on the first calibrating region are or are not electrically connected to each other. A resistance device is provided on the second side of the substrate, wherein the resistance device has a predetermined resistance, and has opposite ends electrically connected to the pads on the second calibrating region.

### BACKGROUND OF THE INVENTION

1. Technical Field

The present invention relates to a device for calibration in a circuit test, and more particularly to a calibration plate.

2. Description of Related Art

Every electronic device has to be tested for its electrical connection before bringing it in the market. It is one of the important issues of the quality control for the electronic devices.

For a precise test, a calibration plate 3, as shown in FIG. 1, is provided to calibrate the probe card, which is used to test the electronic devices. In the calibration task, the operator touches the tips of the probes of the probe card with pads 611, 621, 631 of the calibration plate 3, and the electrical characters of the pads 611, 621, 631 are tested and compensated. For example, the first pair of pads 611 are tested and compensated in an open circuit, and the second pair of pads 612 are tested and compensated in a short circuit. The third pair of pads 612 are coated with resistance paste to be tested and compensated in a resistance test.

However, it would take a long time to wait for the resistance paste to solidify in the resistance test, and the quantity of the resistance paste on the pads affects the result of the test, so it is hard to control the resistance test with the resistance paste. Furthermore, the probes are stuck into the resistance paste in the resistance test, and sometime the probe is broken when the operator inappropriately removes the probe off the resistance paste.

### BRIEF SUMMARY OF THE INVENTION

In view of the above, the primary objective of the present invention is to provide a calibration plate, which shortens the time for test, provides an easy way to control the test, and reduces the chance of breaking the probe.

In order to achieve the objective of the present invention, a substrate having a first side and a second side opposite to the first side. The substrate further has a first calibrating region and a second calibrating region on the first side, on each of which two pads are provided, and the pads on the first calibrating region are or are not electrically connected to each other. A resistance device is provided on the second side of the substrate, wherein the resistance device has a predetermined resistance, and has opposite ends electrically connected to the pads on the second calibrating region.

In an embodiment, the substrate is provided with a recess between the pads on the second calibrating region, and the resistance device is received in the recess.

Since the resistance paste is absent in the present invention, so that there will be no waiting time and breaking the probe problems in the present invention.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a sectional view of the conventional calibration plate;

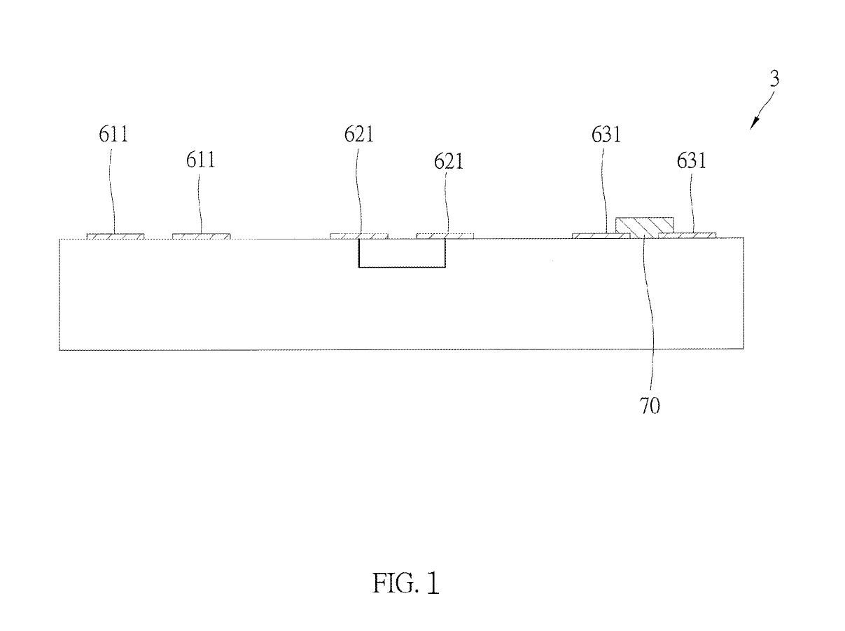

FIG. 2 is a sectional view of a first preferred embodiment of the present invention;

FIG. 3 is a sectional view of a second preferred embodiment of the present invention; and

FIG. 4 is a sectional view of a third preferred embodiment of the present invention.

### DETAILED DESCRIPTION OF THE INVENTION

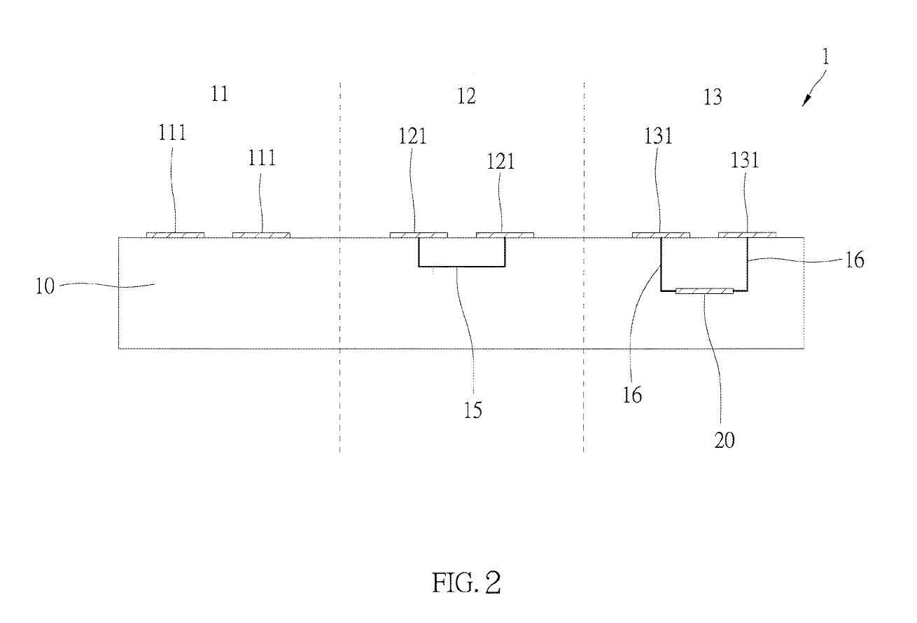

As shown in FIG. 2, a calibration plate 1 of the first preferred embodiment of the present invention includes a substrate 10 and a resistance device 20.

The substrate 10 is a multilayer printed circuit board in the first embodiment, having a first calibrating region 11, a second calibrating region 12, and a third calibrating region 13, on each of which two pads 111, 121, 131 are provided. The pads 111 on the first calibrating region 11 are not electrically connected with each other (open circuit), and the pads 121 on the second calibrating region 12 are electrically connected with each other through a circuit 15 in the substrate 10 (short circuit).

The resistance device 20 has an embedded resistor, having a predetermined resistance, and embedded in the substrate 10. The resistance device 20 has opposite ends electrically connected to the pads 131 of the third calibrating region 13, therefore, there is a resistance between the pads 131 of the third calibrating region 13. In the present embodiment, the resistance of the resistance device 20 is 50Ω, and it could be 75Ω, 100Ω, or other resistances.

With the design of above, no resistance paste is needed in the calibration plate 1 of the present invention, and the probes will directly touch the pads for calibration, so that there would be no waiting time and breaking the probe problem because the resistance paste is absent.

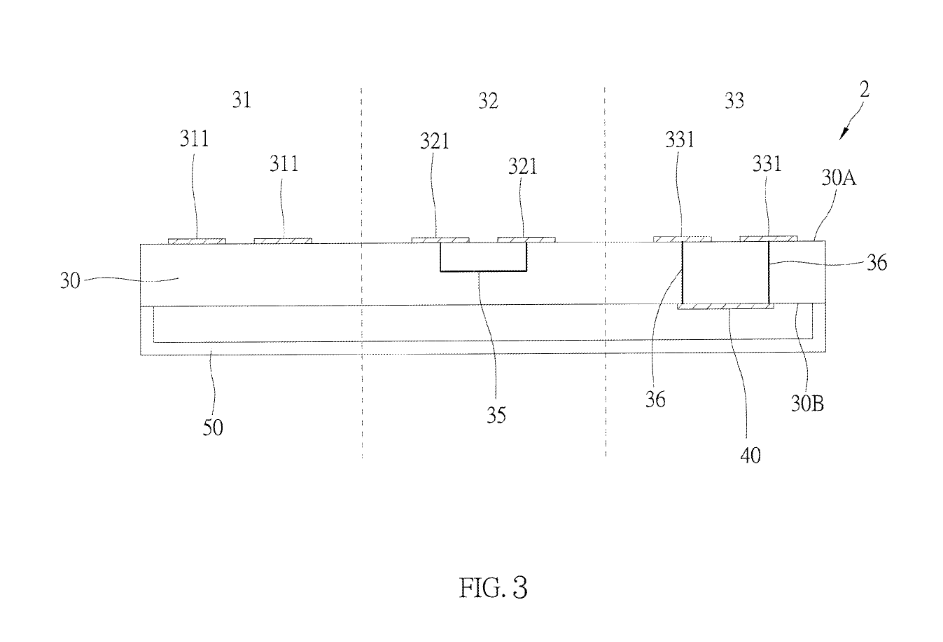

FIG. 3 shows a calibration plate 2 of the second preferred embodiment of the present invention including a substrate 30, a resistance device 40, and a cover 50.

The substrate 10 is a single-layer printed circuit board in the second embodiment, having a first side 30A and a second side 30B opposite to the first side 30A. The substrate 10 is provided with a first calibrating region 31, a second calibrating region 32, and a third calibrating region 33 on the first side 30A. Each calibrating region 31, 32, 33 is provided with two pads 311, 321, 331. The pads 311 on the first calibrating region 31 are not electrically connected with each other (open circuit), and the pads 321 on the second calibrating region 32 are electrically connected with each other through a circuit 35 in the substrate 30 (short circuit).

The resistance device 40 has a resistor with a predetermined resistance, and the resistor is connected to the second side 30B of the substrate 30 by soldering. The resistance device 40 has opposite ends electrically connected to the pads 331 of the third calibrating region 33 on the first side 30A through a circuit 36 in the substrate 30, and therefore, there is a resistance between the pads 331 of the third calibrating region 33. In the present embodiment, the resistance of the resistance device 40 is 50Ω, and it could be 75Ω, 100Ω, or other resistances. The resistance of the resistance device 40 would be a little different from the resistance between the pads 331. A measurement for the exact resistance between the pads is required.

The cover 50 is provided on the second side 30B the substrate 30 to cover the resistance device 40 on the second side 30B. The cover 50 provides the resistance device 40 and any other device on the second side 30B of the substrate 30 a protection, and gives a flat bottom to put the calibration plate 2 stably on any surface.

The calibration plate 2 of the second preferable embodiment serves the same functions as the first preferable embodiment.

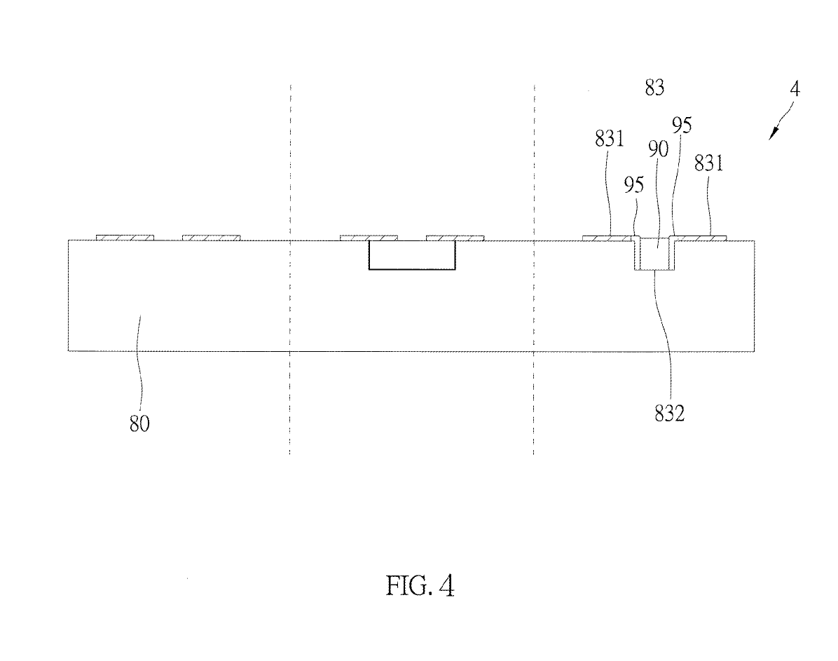

FIG. 4 shows a calibration plate 3 of the third preferred embodiment of the present invention including a substrate 80 and a resistance device 90. The calibration plate 3 is the same as the calibration plate 1 of the first preferable embodiment, except that the substrate is provided with a recess 832 between pads 831 on a third calibrating region 83, and the resistance device 90 is received in the recess 832. Opposite ends of the resistance device 90 are electrically connected to the pads 831 through a conductor 95, such as wirings or solders. As a result, a top of the resistance device 90 is lower than tops of the pads 831 on the third calibrating region 83. In some situations, the top of the resistance device 90 in the recess 832 could be even to the tops of the pads 831. The calibration plate 3 of the third preferred embodiment serves the same functions as above.

It must be pointed out that the embodiments described above are only some preferred embodiments of the present invention. The calibrating regions can be designed to test in open circuit, short circuit, or for resistance test. For example, the first calibrating region could be designed to test in short circuit or resistance test, the second calibrating region could be designed to test in open circuit or resistance test, and the third calibrating region could be designed to test in open circuit or short circuit. The resistance device could be resistors in parallel and/or series to obtain the desired resistance. All equivalent structures which employ the concepts disclosed in this specification and the appended claims should fall within the scope of the present invention.

What is claimed is:

1. A calibrating plate, comprising:
a substrate having a first side and a second side opposite to the first side, wherein the substrate has a first calibrating region and a second calibrating region on the first side, on each of which two pads are provided, and the pads on the first calibrating region are not electrically connected to each other; and
a resistance device provided on the second side of the substrate, wherein the resistance device has a predetermined resistance, and has opposite ends electrically connected to the pads on the second calibrating region.

2. The calibrating plate of claim 1, wherein the substrate further has a third calibrating region, on which two pads are provided, and the pads on the third calibrating region are electrically connected to each other.

3. The calibrating plate of claim 1, further comprising a cover connected to the second side of the substrate to cover the resistance device.

4. A calibrating plate, comprising:
a substrate having a first side and a second side opposite to the first side, wherein the substrate has a first calibrating region and a second calibrating region on the first side, on each of which two pads are provided, and the pads on the first calibrating region are electrically connected to each other; and
a resistance device provided on the second side of the substrate, wherein the resistance device has a predetermined resistance, and has opposite ends electrically connected to the pads on the second calibrating region.

5. The calibrating plate of claim 4, further comprising a cover connected to the second side of the substrate to cover the resistance device.

6. A calibrating plate, comprising:
a substrate having a first side and a second side opposite to the first side, wherein the substrate has a first calibrating region and a second calibrating region on the first side, on each of which two pads are provided, and the pads on the first calibrating region are not electrically connected to each other; and
a resistance device having a predetermined resistance, wherein the resistance device is embedded the substrate, and has opposite ends electrically connected to the pads on the second calibrating region.

7. The calibrating plate of claim 6, wherein the substrate further has a third calibrating region, on which two pads are provided, and the pads on the third calibrating region are electrically connected to each other.

8. A calibrating plate, comprising:
a substrate having a first side and a second side opposite to the first side, wherein the substrate has a first calibrating region and a second calibrating region on the first side, on each of which two pads are provided, and the pads on the first calibrating region are electrically connected to each other; and
a resistance device having a predetermined resistance, wherein the resistance device is embedded the substrate, and has opposite ends electrically connected to the pads on the second calibrating region.

9. A calibrating plate, comprising:
a substrate having a first side and a second side opposite to the first side, wherein the substrate has a first calibrating region and a second calibrating region on the first side, on each of which two pads are provided, and the pads on the first calibrating region are not electrically connected to each other; and
a resistance device having a predetermined resistance, and having opposite ends electrically connected to the pads on the second calibrating region;
wherein the substrate is provided with a recess between the pads on the second calibrating region, and the resistance device is received in the recess.

10. The calibrating plate of claim 9, wherein the substrate further has a third calibrating region, on which two pads are provided, and the pads on the third calibrating region are electrically connected to each other.

11. The calibrating plate of claim 9, wherein a top of the resistance device is even to or lower than tops of the pads on the second calibrating region.

12. A calibrating plate, comprising:
a substrate having a first side and a second side opposite to the first side, wherein the substrate has a first calibrating region and a second calibrating region on the first side, on each of which two pads are provided, and the pads on the first calibrating region are electrically connected to each other; and
a resistance device having a predetermined resistance, and having opposite ends electrically connected to the pads on the second calibrating region;
wherein the substrate is provided with a recess between the pads on the second calibrating region, and the resistance device is received in the recess.

13. The calibrating plate of claim 12, wherein a top of the resistance device is even to or lower than tops of the pads on the second calibrating region.
